(19) United States
(12) Patent Application Publication
(10) Pub. No.: US 2024/0186140 A1
(43) Pub. Date: Jun. 6, 2024

(54) Method for Forming Mixed Substrate

(71) Applicant: Shanghai Huali Microelectronics Corporation, Shanghai (CN)

(72) Inventor: Tao Wang, Shanghai (CN)

(73) Assignee: Shanghai Huali Microelectronics Corporation, Shanghai (CN)

(21) Appl. No.: 18/221,976

(22) Filed: Jul. 14, 2023

(30) Foreign Application Priority Data
Dec. 1, 2022 (CN) 202211534046.2

(51) Int. Cl. H01L 21/02

(52) U.S. Cl. CPC H01L 21/02639; H01L 21/02236; H01L 21/02255

(57) ABSTRACT

The present application discloses a method for forming a mixed substrate. By optimizing the process flow, adding a silicon oxide sidewall process and covering an SOI area sidewall after dry etching with protective silicon oxide, epitaxial silicon growth on the SOI area sidewall is prevented, so that a bulge is prevented from being formed at a boundary between an SOI area and a silicon substrate area when the silicon substrate area is formed on an SOI silicon wafer. At the same time, since STI is eventually formed at the boundary between the SOI area and the silicon substrate area, the actual structure of a device formed on the mixed substrate remains basically unchanged, thus improving the product yield. The method for forming the mixed substrate is particularly suitable for an SOI gate-last process.

### CROSS-REFERENCE TO RELATED APPLICATIONS

This application claims priority to Chinese Patent Application No. 202211534046.2 filed on Dec. 1, 2022, the disclosure of which is incorporated herein by reference in its entirety.

### TECHNICAL FIELD

The present application relates to semiconductor manufacturing technology, in particular to a method for forming a mixed substrate.

### BACKGROUND

For the SOI (Silicon-On-Insulator) process, it is necessary to remove BOX (buried silicon oxide) and SOI in some areas to form a silicon substrate area, which is used for applying voltage to a well area and form structures such as diodes.

In a case that FDSOI (Fully Depleted SOI) adopts a gate-last process, it is necessary to make the silicon substrate area flush with the SOI area to ensure that CMP (Chemical-Mechanical Polishing) can be performed normally in the future.

The existing process flow includes:
(1) depositing a layer of silicon oxide on an SOI silicon wafer, and then depositing a layer of silicon nitride;
(2) performing a photolithography process to open an area in which a silicon substrate is to be formed;
(3) performing dry etching to remove silicon nitride, silicon oxide, SOI and BOX in the silicon substrate area;
(4) removing photoresist; and
(5) performing epitaxial silicon growth to enable the silicon substrate area to grow flush with the SOI area.

However, due to the exposure of the side surface of SOI during epitaxial silicon growth, silicon can also undergo epitaxial growth. After contacting and connecting with the silicon grown at the bottom, a higher bulge 6 is formed at a boundary between SOI and the silicon substrate, as illustrated in FIG. 1, which may cause partial silicon peeling and uneven thickness of a BARC (Bottom Anti-Reflective Coating) during subsequent AA photo (Active Area photolithography). Some areas are too thick, resulting in block etching.

### BRIEF SUMMARY

The technical problem to be solved by the present application is to provide a method for forming a mixed substrate, which can prevent a bulge from being formed at a boundary between an SOI area and a silicon substrate area when the silicon substrate area is formed, and improve the product yield.

In order to solve the technical problem, the method for forming the mixed substrate provided in the present application includes the following steps:
S1: depositing a layer of mask silicon oxide 4 on an SOI silicon wafer, and then depositing a layer of mask silicon nitride 5;
S2: performing a photolithography process to open a silicon substrate area in which a silicon substrate is to be formed;
S3: performing dry etching to remove the mask silicon nitride 5, the mask silicon oxide 4, SOI 3 and BOX 2 above the substrate silicon 1 in the silicon substrate area;
S4: removing photoresist;
S5: oxidizing silicon on an upper surface of the substrate silicon 1 in the silicon substrate area and a side surface of an SOI area to form protective silicon oxide 7;
S6: depositing supplementary silicon oxide 8;
S7: performing dry etching to remove silicon oxide on the substrate silicon 1 in the silicon substrate area; and
S8: performing epitaxial silicon 9 growth to enable the upper surface of the substrate silicon 1 in the silicon substrate area to grow flush with an upper surface of SOI 3 in the SOI area.

Exemplarily, STI is formed at a boundary between the SOI area and the silicon substrate area.

Exemplarily, the supplementary silicon oxide 8 is ALD silicon oxide.

Exemplarily, the thickness of the supplementary silicon oxide 8 is 4-10 nm.

Exemplarily, in step S1, the thickness of the mask silicon oxide 4 is 3-10 nm, and the thickness of the mask silicon nitride 5 is 10-30 nm.

Exemplarily, after dry etching in step S7, wet cleaning is performed and then step S8 is performed.

Exemplarily, in step S5, the silicon on the upper surface of the substrate silicon 1 in the silicon substrate area and the side surface of SOI 3 in the SOI area is oxidized to form the protective silicon oxide 7 through an RTO process.

Exemplarily, in step S5, the thickness of the protective silicon oxide 7 formed by oxidizing the silicon on the upper surface of the substrate silicon 1 in the silicon substrate area and the side surface of SOI 3 in the SOI area is 6-12 nm.

Exemplarily, in step S7, dry etching is performed to remove silicon oxide in the silicon substrate area and the lateral thickness of remaining silicon oxide on the side surface of SOI 3 in the SOI area is enabled to be greater than 3 nm.

In the method for forming the mixed substrate according to the present application, by optimizing the process flow, adding a silicon oxide sidewall process and covering an SOI area sidewall after dry etching with protective silicon oxide, epitaxial silicon growth on the SOI area sidewall is prevented, so that a bulge is prevented from being formed at a boundary between an SOI area and a silicon substrate area when the silicon substrate area is formed on an SOI silicon wafer. At the same time, since STI (Shallow Trench Isolation) is eventually formed at the boundary between the SOI area and the silicon substrate area, the actual structure of a device formed on the mixed substrate remains basically unchanged, thus improving the product yield. The method for forming the mixed substrate is particularly suitable for an SOI gate-last process.

### BRIEF DESCRIPTION OF THE DRAWINGS

In order to describe the technical solution of the present application more clearly, the drawings to be used in the present application will be briefly introduced below. Obviously, the drawings in the following description are only some embodiments of the present application. Those skilled in the art may obtain other drawings according to these drawings without contributing any inventive labor.

FIG. 1 illustrates a structural schematic diagram after epitaxial silicon growth in an existing process flow.

FIG. 2 illustrates a structural schematic diagram after depositing mask silicon oxide and mask silicon nitride.

FIG. 3 illustrates a structural schematic diagram after removing mask silicon nitride, mask silicon oxide, SOI and BOX in a silicon substrate area through dry etching.

FIG. 4 illustrates a structural schematic diagram after oxidizing silicon on a side surface of an SOI area to form protective silicon oxide in a method for forming a mixed substrate according to an embodiment of the present application.

FIG. 5 illustrates a structural schematic diagram when depositing supplementary silicon oxide in a method for forming a mixed substrate according to an embodiment of the present application.

FIG. 6 illustrates a structural schematic diagram after removing silicon oxide on substrate silicon in a silicon substrate area through dry etching in a method for forming a mixed substrate according to an embodiment of the present application.

FIG. 7 illustrates a structural schematic diagram after epitaxial silicon growth in a method for forming a mixed substrate according to an embodiment of the present application.

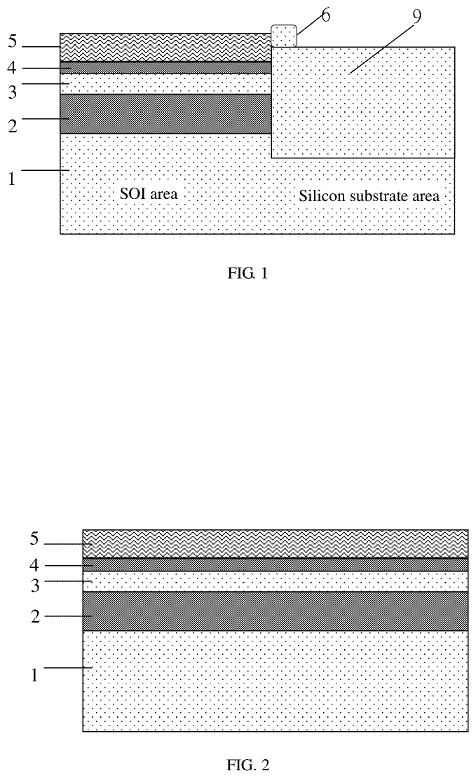

### DESCRIPTION OF REFERENCE SIGNS IN DRAWINGS

1—substrate silicon, 2—BOX (buried silicon oxide), 3—SOI (Silicon-On-Insulator), 4—mask silicon oxide, 5—mask silicon nitride, 6—bulge formed by epitaxial silicon growth, 7—protective silicon oxide, 8—supplementary silicon oxide, 9—epitaxial silicon

### DETAILED DESCRIPTION OF THE APPLICATION

The technical solutions in the embodiments of the present application will be clearly and completely described below with reference to the drawings in the embodiments of the present application. Obviously, the described embodiments are only a part of the embodiments of the present application, instead of all of them. Based on the embodiments of the present application, all other embodiments obtained by those skilled in the art without contributing any inventive labor still fall within the scope of protection of the present application.

The words such as “first” and “second” used in the present application do not indicate any order, quantity, or importance, but are only intended to distinguish different components. The word such as “including” or “comprising” refers to that a component or object that appears before the word includes a component or object listed after the word and its equivalent, without excluding other components or objects. The word such as “connecting” or “connected” is not limited to physical or mechanical connection, but may include electrical connection, whether direct or indirect. The terms such as “up”, “down”, “left” and “right” are only intended to represent relative positional relationships. When the absolute position of a described object changes, the relative positional relationship may also change accordingly.

It is to be understood that the embodiments and the features in the embodiments of the present application may be combined with each other without causing any conflict.

### Embodiment 1

A method for forming a mixed substrate includes the following steps:

S1: depositing a layer of mask silicon oxide 4 on an SOI (Silicon-On-Insulator) silicon wafer, and then depositing a layer of mask silicon nitride 5, as illustrated in FIG. 2;

S2: performing a photolithography process to open a silicon substrate area in which a silicon substrate is to be formed;

S3: performing dry etching to remove the mask silicon nitride 5, the mask silicon oxide 4, SOI 3 and BOX (buried silicon oxide) 2 above the substrate silicon 1 in the silicon substrate area;

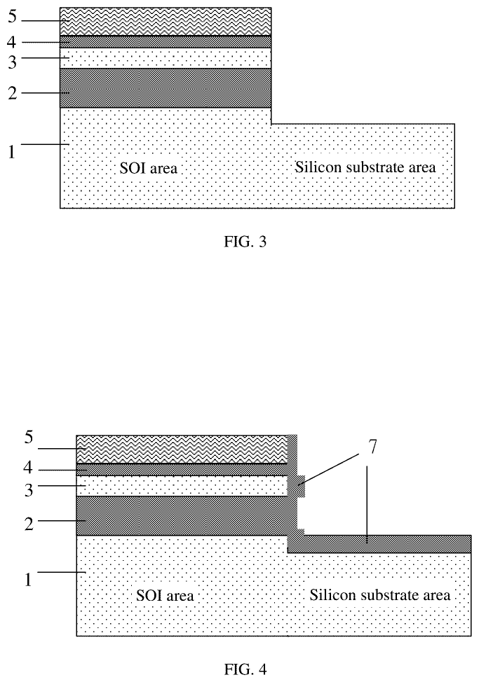

S4: removing photoresist, as illustrated in FIG. 3;

S5: oxidizing silicon on an upper surface of the substrate silicon 1 in the silicon substrate area and a side surface of an SOI area to form protective silicon oxide 7, as illustrated in FIG. 4;

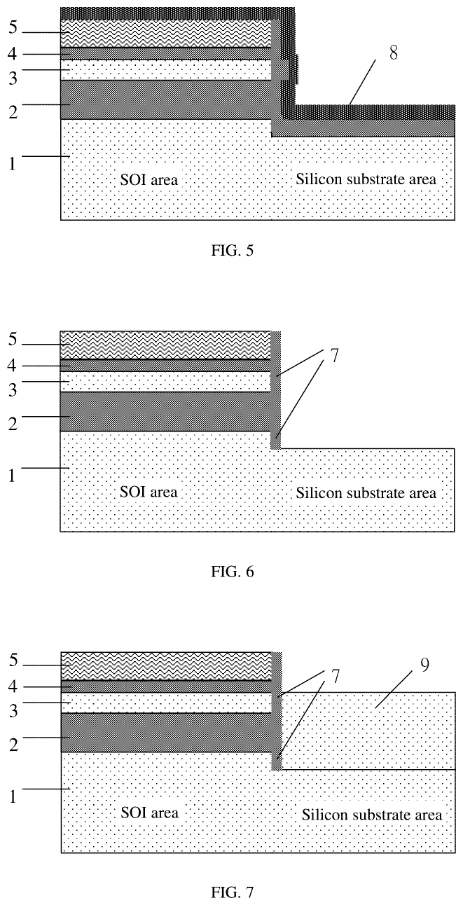

S6: depositing supplementary silicon oxide 8, as illustrated in FIG. 5;

S7: performing dry etching to remove silicon oxide on the substrate silicon 1 in the silicon substrate area, as illustrated in FIG. 6, where due to the directionality of dry etching, the silicon oxide on the side surface of the SOI area only has a small loss.; due to the selection ratio of different film layers in dry etching, the mask silicon nitride 5 on the top of the SOI area only has a small loss; and

S8: performing epitaxial silicon 9 growth to enable the upper surface of the substrate silicon 1 in the silicon substrate area to grow flush with an upper surface of SOI 3 in the SOI area.

Exemplarily, STI (Shallow Trench Isolation) is formed at a boundary between the SOI area and the silicon substrate area.

In the method for forming the mixed substrate according to embodiment 1, by optimizing the process flow, adding a silicon oxide sidewall process and covering an SOI area sidewall after dry etching with protective silicon oxide 7, epitaxial silicon growth on the SOI area sidewall is prevented, so that a bulge is prevented from being formed at a boundary between an SOI area and a silicon substrate area when the silicon substrate area is formed on an SOI silicon wafer. At the same time, since STI is eventually formed at the boundary between the SOI area and the silicon substrate area, the actual structure of a device formed on the mixed substrate remains basically unchanged, thus improving the product yield. By depositing the supplementary silicon oxide 8 to improve the morphology of the protective silicon oxide 7 formed through oxidization, dry etching is facilitated. The method for forming the mixed substrate is particularly suitable for an SOI gate-last process.

### Embodiment 2

Based on the method for forming the mixed substrate according to embodiment 1, the supplementary silicon oxide 8 is ALD (Atomic Layer Deposition) silicon oxide.

Exemplarily, the thickness of the supplementary silicon oxide 8 is 4-20 nm.

Exemplarily, in step S1, the thickness of the mask silicon oxide 4 is 3-10 nm, and the thickness of the mask silicon nitride 5 is 10-30 nm.

### Embodiment 3

Based on the method for forming the mixed substrate according to embodiment 1 or 2, after dry etching in step S7, wet cleaning is performed to remove a byproduct possibly produced in dry etching and then step S8 is performed.

### Embodiment 4

Based on the method for forming the mixed substrate according to embodiment 1, 2 or 3, in step S5, the silicon on the upper surface of the substrate silicon 1 in the silicon substrate area and the side surface of SOI 3 in the SOI area is oxidized to form the protective silicon oxide 7 through an RTO (Rapid Thermal Oxidation) process.

Exemplarily, in step S5, the thickness of the protective silicon oxide 7 formed by oxidizing the silicon on the upper surface of the substrate silicon 1 in the silicon substrate area and the side surface of SOI 3 in the SOI area is 6-12 nm.

Exemplarily, in step S7, dry etching is performed to remove silicon oxide in the silicon substrate area and the lateral thickness of remaining silicon oxide on the side surface of SOI 3 in the SOI area is enabled to be greater than 3 nm.

In the method for forming the mixed substrate according to claim 4, due to the use of the RTO process, only the areas with silicon on the surface are oxidized to form the protective silicon oxide 7, and the protective silicon oxide 7 formed through the RTO process is very dense, which serves as a protective layer and is not easily consumed by processes such as wet process.

What are described above are just exemplary embodiments of the present application and are not intended to limit the present application. Any modifications, equivalent replacements, improvements and the like made within the spirit and principle of the present application should be included within the scope of protection of the present application.

What is claimed is:

1. A method for forming a mixed substrate, comprising the following steps:
S1: depositing a layer of mask silicon oxide on a silicon-on-insulator (SOI) silicon wafer, and then depositing a layer of mask silicon nitride;
S2: performing a photolithography process to open a silicon substrate area in which a silicon substrate is to be formed;
S3: performing dry etching to remove the mask silicon nitride, the mask silicon oxide, SOI, and buried silicon oxide (BOX) above substrate silicon in the silicon substrate area;
S4: removing photoresist;
S5: oxidizing silicon on an upper surface of the substrate silicon in the silicon substrate area and a side surface of an SOI area to form protective silicon oxide;
S6: depositing supplementary silicon oxide;
S7: performing dry etching to remove silicon oxide on the substrate silicon in the silicon substrate area; and
S8: performing epitaxial silicon growth to enable the upper surface of the substrate silicon in the silicon substrate area to grow flush with an upper surface of SOI in the SOI area.

2. The method for forming the mixed substrate according to claim 1, wherein shallow trench isolation (STI) is formed at a boundary between the SOI area and the silicon substrate area.

3. The method for forming the mixed substrate according to claim 1, wherein the supplementary silicon oxide is atomic layer deposition (ALD) silicon oxide.

4. The method for forming the mixed substrate according to claim 1, wherein a thickness of the supplementary silicon oxide is 4-20 nm.

5. The method for forming the mixed substrate according to claim 1, wherein in step S1, a thickness of the mask silicon oxide is 3-10 nm, and a thickness of the mask silicon nitride is 10-30 nm.

6. The method for forming the mixed substrate according to claim 1, wherein, after dry etching in step S7, wet cleaning is performed and then step S8 is performed.

7. The method for forming the mixed substrate according to claim 1, wherein, in step S5, the silicon on the upper surface of the substrate silicon in the silicon substrate area and the side surface of the SOI in the SOI area is oxidized to form the protective silicon oxide through a rapid thermal oxidation (RTO) process.

8. The method for forming the mixed substrate according to claim 1, wherein, in step S5, a thickness of the protective silicon oxide formed by oxidizing the silicon on the upper surface of the substrate silicon in the silicon substrate area and the side surface of the SOI in the SOI area is 6-12 nm.

9. The method for forming the mixed substrate according to claim 1, wherein, in step S7, dry etching is performed to remove silicon oxide in the silicon substrate area, and a lateral thickness of remaining silicon oxide on the side surface of the SOI in the SOI area is enabled to be greater than 3 nm.
